(19) United States
(12) Patent Application Publication
(10) Pub. No.: US 2006/0091528 A1
(43) Pub. Date: May 4, 2006

(54) High heat dissipation flip chip package structure

(75) Inventor: Ching-Hsu Yang, Taichung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/182,973

(22) Filed: Jul. 18, 2005

(30) Foreign Application Priority Data
Nov. 4, 2004 (TW) 93133663

(51) Int. Cl. H01L 23/34; H01L 23/48

(52) U.S. Cl. 257/706; 257/707; 257/717; 257/720; 257/778

(57) ABSTRACT

A high heat dissipation flip chip package structure including a substrate, a chip, a supporting structure, and a heat spreader is provided. The substrate has a substrate surface. The chip has an active surface with several bumps formed thereon. The bumps are connected to the substrate surface. The supporting structure has an upper part having a first opening and a lower part fixed on the substrate surface. The first opening corresponds to the chip. The heat spreader having at least a second opening is fixed on the upper part. The first opening is connected to outside through the second opening. The heat generated by the chip is not only dissipated to outside through the heat spreader by the heat conduction, but also dissipated to outside by the heat convection at the first opening and the second opening.

This application claims the benefit of Taiwan application Serial No. 93133663, filed Nov. 14, 2004, the subject matter of which is incorporated herein by reference.

### BACKGROUND OF THE INVENTION

1. Field of the Invention

The invention relates in general to a flip chip package structure, and more particularly to a high heat dissipation flip chip package structure.

2. Description of the Related Art

Referring to FIG. 1, a cross-sectional view of a conventional flip chip package structure having a heat spreader is shown. The flip chip package structure 10 includes a substrate 11, a chip 12, an adhesive layer 13, a heat spreader 14 and a number of solder balls 15. The substrate 11 has two substrate surfaces 1a and 1b which are opposite to each other. The chip 12 has an active surface 12a with several bumps 16 formed thereon and a chip back surface 12b which are opposite to each other. The chip 12 uses the bumps 16 to be attached on the substrate surface 11a to be electrically connected to the substrate 11. The heat spreader 14 has a bottom surface 14a and a number of fins 14b. The bottom surface 14a is connected to the chip back surface 12b via the adhesive layer 13. Besides, the solder balls 15 are formed on the substrate surface 11b for the package structure 10 to be electrically connected to an external circuit, such as a printed circuit board (PCB).

The heat spreader 14 is used to dissipate the heat generated by the chip 12 to the outside, lest the chip 12 might break down when overheated. However, in a conventional package structure, the chip 12 directly braces the heat spreader 14 without any other supporting structures. Being weighed by the heat spreader 14, the chip 12 is very likely to be weighed down and damaged, severely affecting the yield rate of the package structure 10.

### SUMMARY OF THE INVENTION

It is therefore the object of the invention to provide a high heat dissipation package structure. The package structure of the invention has a supporting structure to brace the heat spreader, lest the heat spreader might weigh down and damage the chip. Therefore, the invention increases the yield rate of the package structure. Besides, both the heat spreader and the supporting structure have an opening, enabling the heat generated by the chip to be dissipated to outside by heat conduction and heat convection to increase the dissipation efficiency of the package structure.

According to an object of the invention, a high heat dissipation package structure at least including a substrate, a chip, a supporting structure, and a heat spreader is provided. The substrate has a substrate surface. The chip has an active surface with several bumps formed thereon. The bumps are connected to the substrate surface. The supporting structure has an upper part and a lower part. The upper part has a first opening. The lower part is fixed on the substrate surface. The position of the first opening corresponds to the position of the chip. The heat spreader has at least a second opening. The heat spreader is fixed on the upper part of the supporting structure. The second opening and the first opening are connected to each other, so that the first opening is connected to outside through the second opening. The heat generated by the chip is not only dissipated to outside through the heat spreader by heat conduction, but also dissipated to outside by the heat convection at the first opening and the second opening.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view of a conventional flip chip package structure having a heat spreader;

FIG. 2 is a cross-sectional view of a high heat dissipation flip chip package structure according to a first embodiment of the invention;

FIG. 3 is a top view of the supporting structure of FIG. 2;

FIG. 4 is an upward view of the heat spreader of FIG. 2; and

FIG. 5 is a cross-sectional view of a high heat dissipation flip chip package structure according to a second embodiment of the invention.

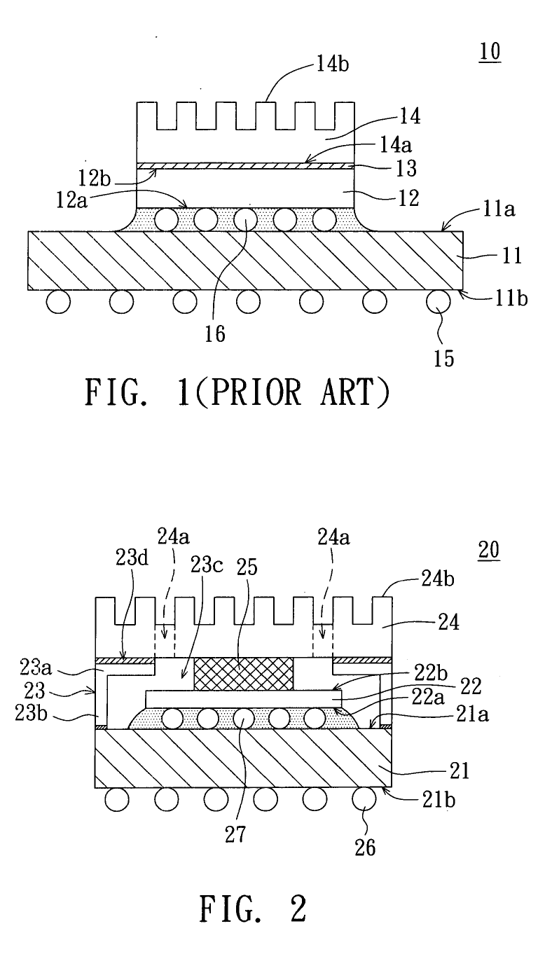

### DETAILED DESCRIPTION OF THE INVENTION

### FIRST EMBODIMENT

Referring to FIG. 2, a cross-sectional view of a high heat dissipation flip chip package structure according to a first embodiment of the invention is shown. The package structure 20 includes a substrate 21, a chip 22, a supporting structure 23 and a heat spreader 24. The substrate 21 has two substrate surfaces 21a and 21b which are opposite to each other. The chip 22 has an active surface 22a with several bumps 27 formed thereon and a chip back surface 22b which are opposite to each other. The chip 22 uses bumps 27 to be attached to the central area of the substrate surface 21a to be electrically connected to the substrate 21. The package structure 20 further includes several solder balls 26 formed on the substrate surface 21b.

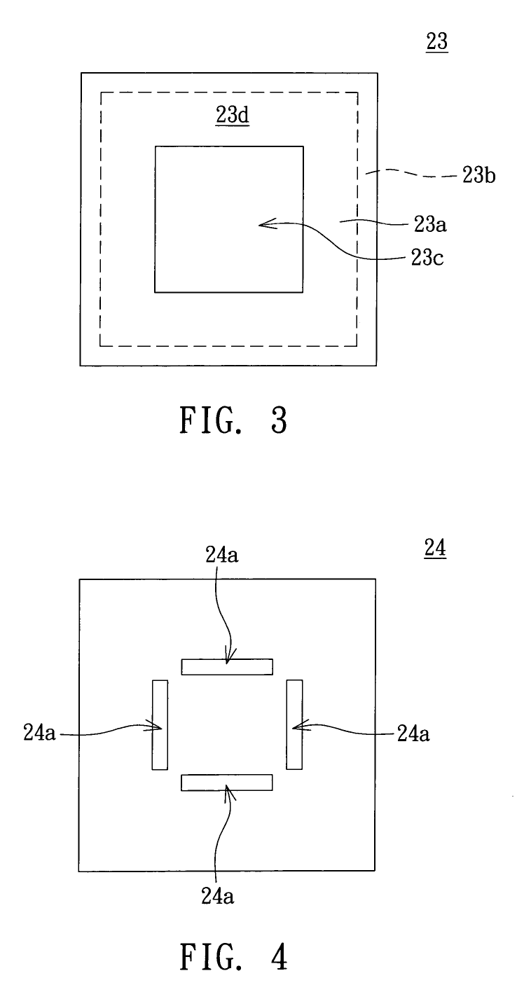

Referring to both FIG. 2 and FIG. 3, wherein FIG. 3 is a top view of the supporting structure of FIG. 2. The supporting structure 23 has an upper part 23a and a lower part 23b. The upper part 23a and the lower part 23b can be integrally formed into a body. In other word, the upper part 23a is formed integrally with the lower part 23b. The upper part 23a has a first opening 23c. The lower part 23b is fixed on the substrate surface 21a. The position of the first opening 23c corresponds to the position of the chip 22. The supporting structure 23 is preferably made of a metal such as aluminum for instance. The supporting structure 23 can be made of a non-metal material such as the thermosetting resin. In the present embodiment, the supporting structure 23 is a helmet-shaped structure with a hollowed top surface, and the upper surface of the upper part 23a is a top surface 23d. The first opening 23c is positioned on the central area of the top surface 23d.

Referring to both FIG. 2 and FIG. 4, wherein FIG. 4 is a top view of the supporting structure of FIG. 2. The heat spreader 24 has at least a second opening 24a. The heat spreader 24 of FIG. 4 has four second openings 24a which are positioned near the wall of the first opening 23c and above the first opening 23c. The size of the second opening 24a is preferably smaller than the size of the first opening 23c. The heat spreader 24 is fixed on the upper part 23a of the supporting structure 23. The second opening 24a and the first opening 23c are connected together, so that the first opening 23c is connected to outside through the second opening 24a. The heat spreader 24 preferably has a number of fins 24b to increase the dissipation efficiency of the heat spreader 24.

To help dissipate the heat generated by the chip 22, the clearance between the chip back surface 22b and the central area of the heat spreader 24 preferably has a thermoconductive structure 25 disposed therein for the chip 22 and the heat spreader 24 to be thermoconductively connected together. The thermoconductive structure 25 can be made of a metal such as copper or silver for instance. The thermoconductive structure 25 can also be made of high thermoconductive resin. The thickness of the thermoconductive structure 25 approximately ranges from 1˜5 (mil). The thermoconductive structure 25 is preferably disposed at a position corresponding to the clearance between the central area of the heat spreader 24 and the central area of the chip 22. The second opening 24a is positioned outside the edge of the thermoconductive structure 25 such that the second opening 24a is not enclosed by the thermoconductive structure 25. In other word, the second opening 24a can't be closed by the thermoconductive structure 25.

When the chip 22 generates heat under normal operation, the heat generated by the chip 22 is not only transmitted to the heat spreader 24 through the thermoconductive structure 25 to be dissipated to outside by heat conduction, but is also dissipated to outside by the heat convection at the first opening 23c and the second opening 24a. That is to say, through several second openings 24a, the hot air around the chip 22 moves upwards so that the heat generated by the chip 22 is dissipated to outside of the package structure 24 via the first opening 23c and the second opening 24a. Meanwhile, the chip 22 is cooled down by the cold air outside the package structure 24 infused into the vicinity of the chip 22 through the second opening 24a and the first opening 23c. Thus, the present embodiment of the invention can effectively increase the dissipation efficiency of the package structure and achieve the object of providing a high heat dissipation package structure.

Besides, the present embodiment has a supporting structure 23.to brace the heat spreader 24, preventing the heat spreader from weighing down and damaging the chip. So, the present embodiment further increases the yield rate of the package structure.

### SECOND EMBODIMENT

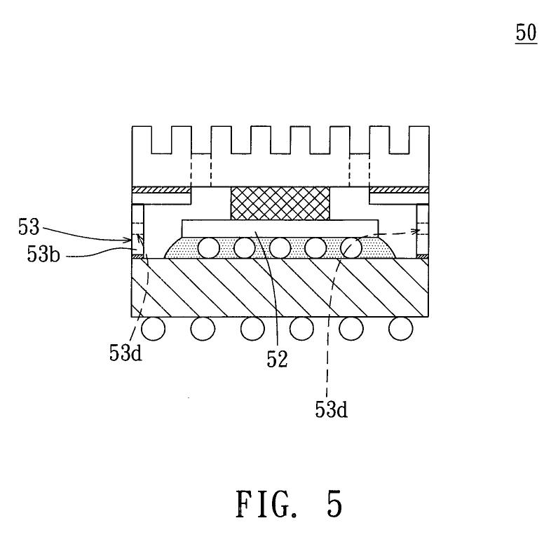

Referring to FIG. 5, a cross-sectional view of a high heat dissipation package structure according to a second embodiment of the invention is shown. The package structure 50 of the present embodiment differs with the package structure 20 of the first embodiment in that the lower part 53b of the supporting structure 53 further has at least a third opening 53d disposed along the lateral side. The heat generated by the chip 52 is further dissipated to outside by the heat convection at the third opening 53d. The disposition of the third opening 53d further enhances the dissipation effect of the package structure 50.

The high heat dissipation package structures are disclosed in above embodiments of the invention. The package structure of the invention has a supporting structure to brace the heat spreader, lest the heat spreader might weigh down and damage the chip. Therefore, the invention increases the yield rate of the package structure. Besides, both the heat spreader and the supporting structure have an opening, enabling the heat generated by the chip to be dissipated to outside by heat conduction and heat convection to increase the dissipation efficiency of the package structure.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A high heat dissipation flip chip package structure, comprising:
a substrate having a substrate surface;
a chip having an active surface with a plurality of bumps formed thereon, wherein the bumps are connected to the substrate surface;
a supporting structure having an upper part and a lower part, wherein the upper part has a first opening, the lower part is fixed on the substrate surface, and the first opening corresponds to the chip; and
a heat spreader having at least a second opening fixed on the upper part, wherein the first opening is connected to outside through the second opening;
wherein the heat generated by the chip is not only dissipated to outside through the heat spreader by the heat conduction, but is also dissipated to outside by the heat convection at the first opening and the second opening.

2. The flip chip package structure according to claim 1, wherein the heat spreader includes a plurality of fins.

3. The flip chip package structure according to claim 1, wherein the second opening is positioned above the first opening, and the size of the second opening is smaller than that of the first opening.

4. The flip chip package structure according to claim 1, the chip further having a chip back surface opposite to the active surface, wherein the flip chip package structure further comprises:
a thermoconductive structure disposed between the chip back surface and the central area of the heat spreader for thermoconductively connecting the chip and the heat spreader.

55. The flip chip package structure according to claim 4, wherein the thermoconductive structure is made of a metal.

6. The flip chip package structure according to claim 5, wherein the thermoconductive structure is made of copper or silver.

7. The flip chip package structure according to claim 4, wherein the thermoconductive structure is made of a high thermoconductive resin.

8. The flip chip package structure according to claim 4, wherein the thermoconductive structure is disposed on between the central area of the heat spreader and the central area of the chip, the second opening is positioned outside the edge of thermoconductive structure.

9. The flip chip package structure according to claim 1, wherein the supporting structure is made of a metal.

10. The flip chip package structure according to claim 9, wherein the supporting structure is made of aluminum.

11. The flip chip package structure according to claim 1, wherein the supporting structure is made of thermosetting resin.

12. The flip chip package structure according to claim 1, wherein the supporting structure is a helmet-shaped structure and the upper part is formed integrally with the lower part.

13. The flip chip package structure according to claim 1, wherein the lower part further has at least a third opening, the heat generated by the chip is further dissipated to outside by the heat convection at the third opening.
